(19) United States
(12) Patent Application Publication
(10) Pub. No.: US 2026/0164685 A1
(43) Pub. Date: Jun. 11, 2026

(54) SEMICONDUCTOR STRUCTURE HAVING DEEP TRENCH CAPACITOR AND METHOD OF MANUFACTURING THEREOF

(71) Applicant: TAIWAN SEMICONDUCTOR MANUFACTURING COMPANY LTD., HSINCHU (TW)

(72) Inventors: TZU JUNG TIEN, HSINCHU COUNTY (TW); CHEUNG CHENG, HSINCHU CITY (TW); CHEN-HSUAN YEN, TAICHUNG CITY (TW); FU-CHIANG KUO, HSINCHU CITY (TW)

(21) Appl. No.: 18/969,324

(22) Filed: Dec. 5, 2024

(51) Int. Cl. H01L 21/02

(52) U.S. Cl. CPC H10D 1/716

(57) ABSTRACT

A semiconductor structure includes a substrate; a capacitor structure including a first plug element and a second plug element, wherein the first plug element and the second plug element extend into the substrate in a first direction, extend along a second direction orthogonal to the first direction, and are aligned with each other along the second direction; and an isolation member disposed between and in contact with the first plug element and the second plug element.

### BACKGROUND

The semiconductor industry has experienced rapid growth due to ongoing improvements in integration density of a variety of electrical components. To accommodate the miniaturized scale of semiconductor devices, various technologies and applications have been developed for wafer-level packaging, involving greater numbers of different components with different functions. Improvements in integration density have resulted from iterative reduction of minimum feature size, allowing more components to be integrated into a given area. Such advances require the semiconductor devices to undergo ever-greater numbers of manufacturing processes.

As semiconductor technologies further advance, embedding of electrical components into a semiconductive substrate has emerged as an effective approach to further reducing a physical size of a semiconductor device. Capacitors are embedded within the semiconductive substrate for many applications, such as power supply stabilization. However, a significant amount of device area is often used to fabricate such capacitors. Accordingly, capacitors that provide a specific capacitance while having a small device footprint are desirable.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is a schematic top view of a semiconductor structure in accordance with some embodiments of the present disclosure.

FIG. 2 is a schematic cross-sectional view taken along a line A-A′ in FIG. 1.

FIG. 3 is a schematic cross-sectional view taken along a line B-B′ in FIG. 1.

FIG. 4 is a schematic cross-sectional view taken along the line A-A′ in FIG. 1.

FIG. 5 is a schematic top view of a portion of a semiconductor structure in accordance with some embodiments of the present disclosure.

FIG. 6 is a schematic top view of a portion of a semiconductor structure in accordance with some embodiments of the present disclosure.

FIG. 7 is a schematic top view of a semiconductor structure in accordance with some embodiments of the present disclosure.

FIG. 8 is a flow diagram of a method of manufacturing a semiconductor structure in accordance with some embodiments of the present disclosure.

FIG. 9 is a flow diagram of a method of manufacturing a semiconductor structure in accordance with some embodiments of the present disclosure.

FIGS. 10, 14A, 15A, 16A and 17A are schematic top views of one or more stages of the method shown in FIG. 9 of manufacturing a semiconductor structure in accordance with some embodiments of the present disclosure.

FIGS. 14B, 15B, 16B and 17B are schematic cross-sectional views taken along a line C-C′ in FIGS. 14A, 15A, 16A and 17A, respectively.

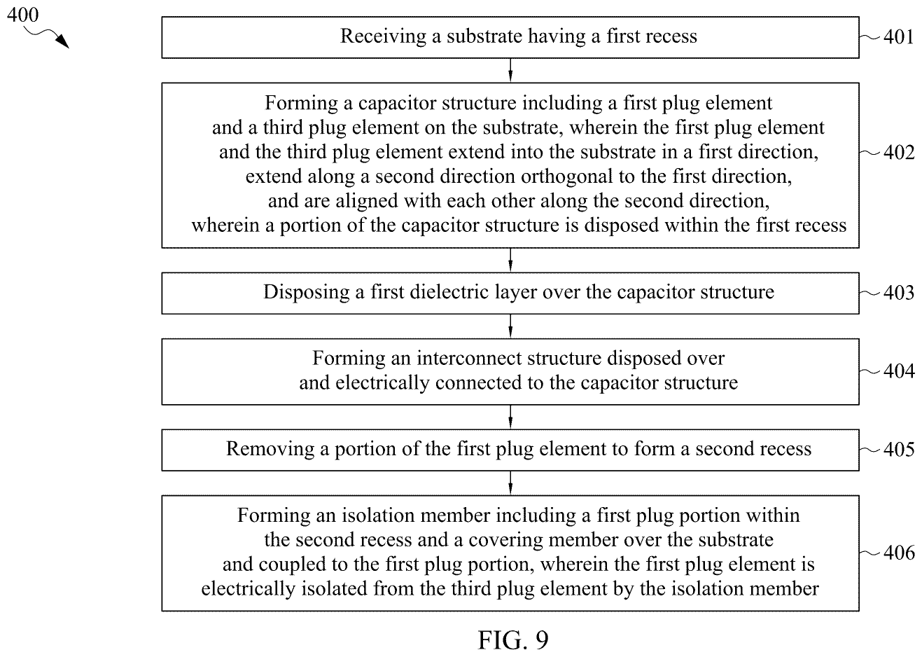

FIGS. 11, 12, 13 and 18 are schematic cross-sectional views of one or more stages of the method shown in FIG. 9 of manufacturing a semiconductor structure in accordance with some embodiments of the present disclosure.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features are not in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “upper,” “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, although the terms such as “first,” “second” and “third” describe various elements, components, regions, layers and/or sections, these elements, components, regions, layers and/or sections should not be limited by these terms. These terms may be only used to distinguish one element, component, region, layer or section from another. The terms such as “first,” “second” and “third” when used herein do not imply a sequence or order unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard variation found in the respective testing measurements. Also, as used herein, the terms “substantially,” “approximately” and “about” generally mean within a value or range that can be contemplated by people having ordinary skill in the art. Alternatively, the terms “substantially,” “approximately” and “about” mean within an acceptable standard error of the mean when considered by one of ordinary skill in the art. People having ordinary skill in the art can understand that the acceptable standard error may vary according to different technologies.

Other than in the operating/working examples, or unless otherwise expressly specified, all of the numerical ranges, amounts, values and percentages such as those for quantities of materials, durations of time, temperatures, operating conditions, ratios of amounts, and the likes thereof disclosed herein should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

In the present disclosure, a semiconductor structure and a method of manufacturing a semiconductor structure are provided. The semiconductor structure includes a substrate with a recess formed in the substrate, a capacitor structure at least partially disposed within the recess, and an isolation member in contact with the capacitor structure. By adjusting a relative position of the capacitor structure and the isolation member, the capacitor structure of the present disclosure may have a specific capacitance.

The capacitor structure includes a deep trench capacitor, which may be used as an integrated passive device to provide large capacitance. Deep trench capacitors may be formed in a first semiconductor die as a component of a power supply circuit. The first semiconductor die may be subsequently bonded to a second semiconductor die, which could be a system-on-a-chip (SoC) semiconductor die. The deep trench capacitors of the present disclosure may have specific capacitances based on properties of the first semiconductor die and/or the second semiconductor die. An overall performance of the semiconductor structure can therefore be increased or improved.

In some embodiments, a method of manufacturing a semiconductor structure includes receiving a substrate; forming a capacitor structure including a first plug element and a second plug element on the substrate, wherein the first plug element and the second plug element extend into the substrate in a first direction, extend along a second direction orthogonal to the first direction, and are aligned with each other along the second direction; removing a portion of the first plug element to form a recess; and forming an isolation member including a first plug portion within the recess. The first plug element is electrically isolated from the second plug element by the isolation member.

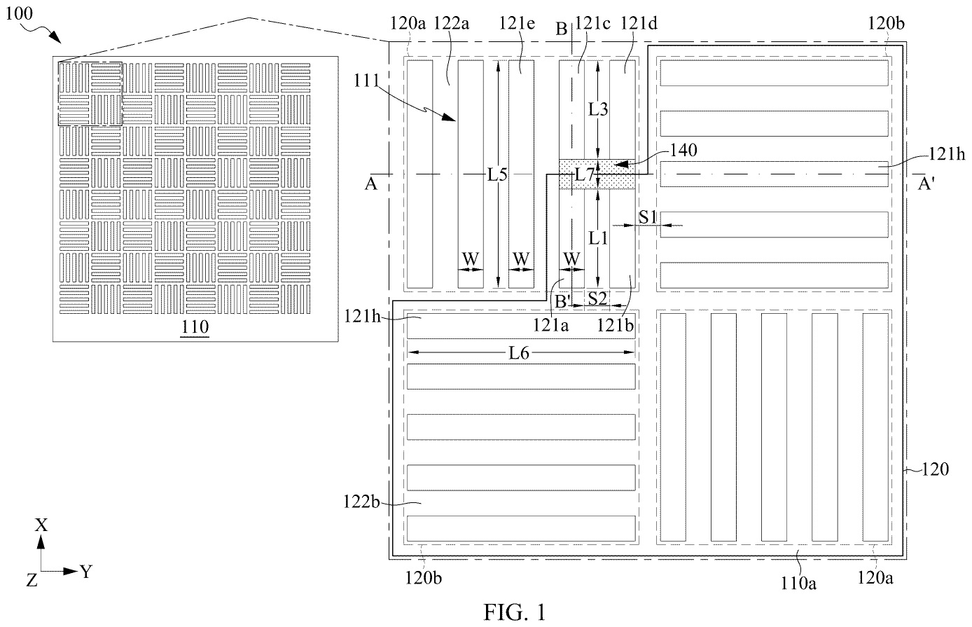

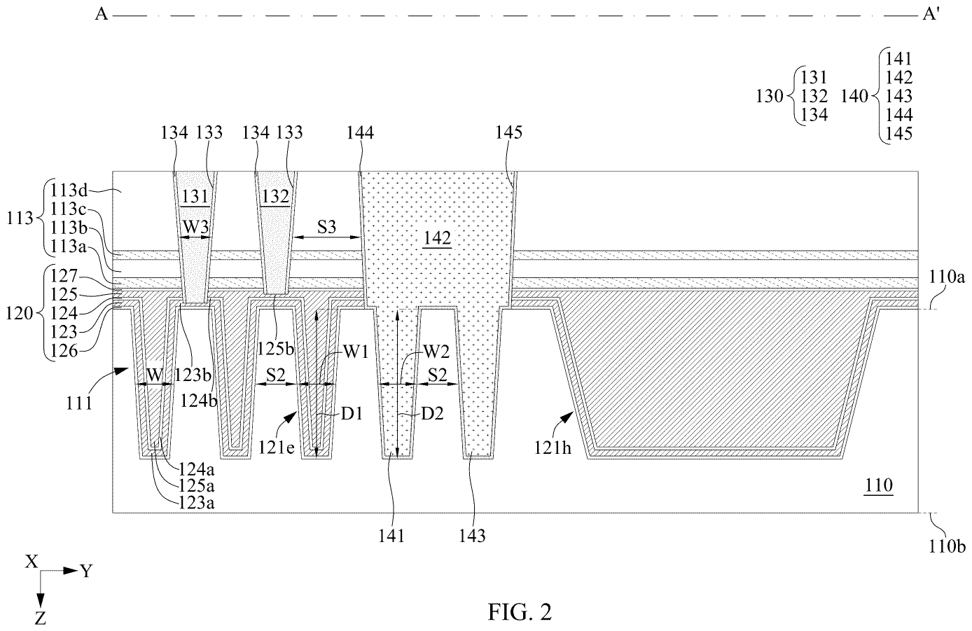

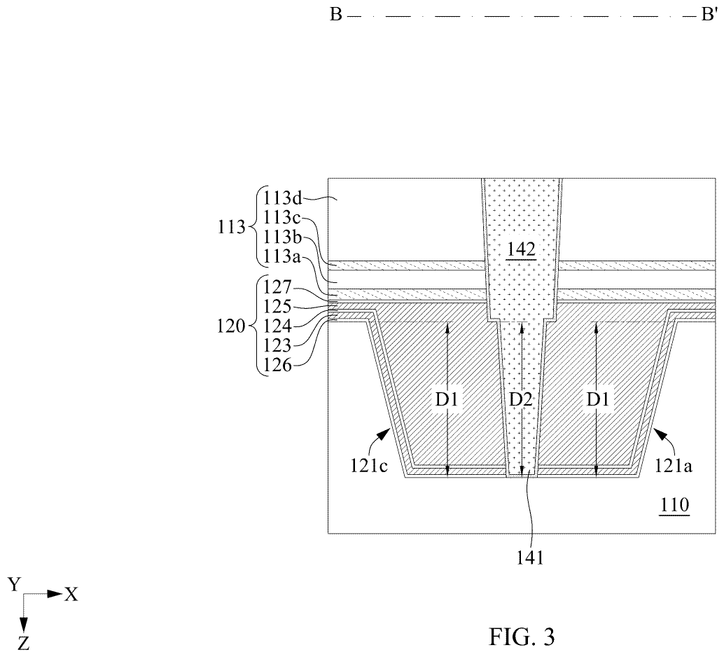

FIG. 1 is a schematic top cross-sectional view of a semiconductor structure in accordance with some embodiments of the present disclosure. FIG. 2 is a schematic cross-sectional view taken along a line A-A′ in FIG. 1. FIG. 3 is a schematic cross-sectional view taken along a line B-B′ in FIG. 1.

Referring to FIG. 1, the semiconductor structure 100 is a chip, a package or a part of a chip or a package. The semiconductor structure 100 includes a substrate 110, a capacitor structure 120 extending into the substrate 110 in a first direction Z, and an isolation member 140 in contact with the capacitor structure 120.

In some embodiments, the substrate 110 includes semiconductive material such as silicon, germanium, gallium, arsenic, or a combination thereof. In some embodiments, the substrate 110 is a semiconductor wafer. In some embodiments, the substrate 110 is a silicon substrate. The substrate 110 includes a first surface 110a and a second surface 110b opposite to the first surface 110a. In some embodiments, the first surface 110a is a front side or an active side with several electrical components disposed thereon. In some embodiments, the second surface 110b is a back side or an inactive side from which electrical components are absent. In some embodiments, the substrate 110 includes a commercially available semiconductor wafer that may be diced into semiconductor dies after formation of the capacitor structure 120 and the isolation member 140. In some embodiments, the substrate 110 has a thickness in a range from 500 to 1,500 μm, although greater or lesser thicknesses may be used.

The substrate 110 includes a first recess 111 formed in the substrate 110. In some embodiments, the first recess 111 extends from the first surface 110a toward the second surface 110b of the substrate 110 in the first direction Z. A dimension, a size and a shape of the first recess 111 may be adjusted according to requirements, and are not particularly limited.

The capacitor structure 120 is at least partially disposed within the first recess 111. In some embodiments, the capacitor structure 120 is configured to provide capacitance for a circuitry in the substrate 110.

In some embodiments, the capacitor structure 120 includes a first plug element 121a, a second plug element 121b, a third plug element 121c, a fourth plug element 121d, a fifth plug element 121e and a sixth plug element 121h. Each of the first, second, third, fourth, fifth and sixth plug elements 121a, 121b, 121c, 121d, 121e and 121h extends into the substrate 110 in the first direction Z and extends along a second direction X or a third direction Y orthogonal to the first direction Z with a width W. In some embodiments, the width W is uniform and in a range from 50 nm to 1,000 nm, although lesser and greater widths may also be used. In some embodiments, the width W is 200 nm. In some embodiments, the predominant portion of the fifth plug element 121e has the width W that is sufficient to accommodate at least two electrode layers and at least two dielectric layers extending along the first direction Z.

In some embodiments, the capacitor structure 120 includes at least one first-type plug group 120a and at least one second-type plug group 120b formed in the first surface 110a of the substrate 110. In some embodiments, the first-type plug group 120a includes the first, second, third, fourth and fifth plug elements 121a, 121b, 121c, 121d and 121e, and the second-type plug group 120b includes the sixth plug element 121h. In some embodiments, the first-type plug group 120a and the second-type plug group 120b laterally alternate along at least one direction that is selected from the second direction X and the third direction Z. In some embodiments, the second direction X is perpendicular to the third direction Y.

In some embodiments, a first distance S1 is between the first-type plug group 120a and the second-type plug group 120b, a second distance S2 is between the first plug element 121a and the second plug element 121b, and the first distance S1 is substantially greater than or equal to 1.45 times the second distance S2. In some embodiments, the first distance S1 is between 0.4 and 0.8 μm. In some embodiments, the first distance S1 is substantially greater than or equal to 2 times the width W, and the second distance S2 is substantially greater than or equal to 1.5 times the width W. In some embodiments, the second distance S2 is 275 nm.

In some embodiments, the first-type plug group 120a and the second-type plug group 120b laterally alternate along the second direction X and the third direction Y. The first-type plug group 120a has first lengthwise sidewalls 122a that laterally extend along the second direction X, and the second-type plug group 120b has second lengthwise sidewalls 122b that laterally extend along the third direction Y that is different from the second direction X.

In some embodiments, the capacitor structure 120 can be considered as a bank of available plug elements, and any number of the plug elements can form the capacitor structure 120 with a capacitance proportional to the number of plug elements. Once the design requirements of a chip to be connected to the capacitor structure 120 are known, a size and a scope of the capacitor structure 120 can be calculated accordingly. In some embodiments, the number of the plug elements is calculated by dividing the target capacitance for the chip by a unit capacitance that one plug element provides.

It should be understood that although the capacitor structure 120 is organized by the first-type plug group 120a and the second-type plug group 120b, a division does not have to follow boundaries of the first-type plug group 120a or the second-type plug group 120b. In other words, boundaries among the capacitor structure 120 can cross the boundaries of the first-type plug group 120a and/or the boundaries of the second-type plug group 120b.

In some embodiments, the isolation member 140 divides the first-type plug group 120a up to design requirement. In some embodiments, the isolation member 140 is formed within the first-type plug group 120a. As such, a portion of the first-type plug group 120a can be part of (i.e., can be included in) the capacitor structure 120, while another portion of the first-type plug group 120a can be part of (i.e., can be included in) another capacitor structure or can be unused and reserved for future use. In some embodiments, some plug elements of the first-type plug group 120a are used (i.e., assigned to the capacitor structure 120), and some plug elements of the first-type plug group 120a can be unused (i.e., not assigned to any capacitor structure 120, and reserved for future use).

In some embodiments, the first plug element 121a and the second plug element 121b assigned to the capacitor structure 120 are electrically connected by, for example, metal tracks in one or more electrode layers. Routing resources can be allocated according to geometry, location, and size of the corresponding capacitor structure 120.

In some embodiments, the first plug element 121a and the third plug element 121c are aligned with each other along the second direction X, and the isolation member 140 is disposed between and in contact with the first plug element 121a and the third plug element 121c. The isolation member 140 insulates the first plug element 121a from the third plug element 121c.

The first plug element 121a has a first length L1 along the second direction X, and the third plug element 121c has a third length L3 along the second direction X. In some embodiments, since the isolation member 140 is disposed between the first plug element 121a and the third plug element 121c, a position of the isolation member 140 is related to the first length L1 and the third length L3.

In some embodiments, the fifth plug element 121e of the first-type plug group 120a is disposed extending along the second direction X and adjacent to the first plug element 121a, the third plug element 121c and the isolation member 140. In some embodiments, the fifth plug element 121e has a fifth length L5 along the second direction X, wherein the fifth length L5 is substantially greater than the first length L1 and substantially greater than the third length L3. In some embodiments, the sixth plug element 121h of the second-type plug group 120b is disposed extending along the third direction Y and has a sixth length L6 along the third direction Y, wherein the sixth length L6 is substantially greater than the first length L1 and substantially greater than the third length L3.

In some embodiments, the fifth length L5 of the fifth plug element 121e is equal to a sum of the first length L1 of the first plug element 121a, the third length L3 of the third plug element 121c and a seventh length L7 of the isolation member 140 along the second direction X. In some embodiments, the fifth plug element 121e is adjacent to the first plug element 121a, the third plug element 121c and the isolation member 140 along the third direction Y. In some embodiments, the sixth length L6 of the sixth plug element 121h along the third direction Y is equal to a sum of the first length L1 of the first plug element 121a, the third length L3 of the third plug element 121c and the seventh length L7 of the isolation member 140 along the second direction X. In some embodiments, the seventh length L7 of the isolation member 140 is between 6 μm and 15 μm.

In some embodiments, the second plug element 121b and the fourth plug element 121d are aligned with each other along the second direction X, the first plug element 121a is adjacent to the second plug element 121b, and the third plug element 121c is adjacent to the fourth plug element 121d. In some embodiments, the isolation member 140 is further disposed between and in contact with the second plug element 121b and the fourth plug element 121d.

In some embodiments, the first plug element 121a and the third plug element 121c are electrically connected to each other, and electrically isolated from the second plug element 121b, the fourth plug element 121d and the fifth plug element 121e. In some embodiments, the first plug element 121a and the third plug element 121c are electrically connected to the second-type plug group 120b, including the sixth plug element 121h.

Referring to FIGS. 1, 2 and 3, the isolation member 140 includes a first plug portion 141 extending into the substrate 110 in the first direction Z and disposed between the first plug element 121a and the third plug element 121c. The isolation member 140 further includes a covering member 142 disposed over the first plug portion 141. In some embodiments, a portion of the capacitor structure 120 is disposed over the first surface 110a of the substrate 110, and the covering member 142 of the isolation member 140 is in contact with the portion of the capacitor structure 120.

In some embodiments, the isolation member 140 further includes a second plug portion 143 extending into the substrate 110 in the first direction Z and disposed between the second plug element 121b and the fourth plug element 121d. In some embodiments, the covering member 142 is disposed over the first plug portion 141 and the second plug portion 143. In some embodiments, the first plug portion 141, the second plug portion 143 and the covering member 142 are integral and continuous.

Each of the first, second, third, fourth, fifth and sixth plug elements 121a, 121b, 121c, 121d, 121e, and 121h has a first depth D1 along the first direction Z, and the first plug portion 141 of the isolation member 140 has a second depth D2 along the first direction Z. In some embodiments, the first depth D1 is substantially equal to or less than the second depth D2. In some embodiments, the first plug element 121a has a first width W1 along the third direction Y and the first plug portion 141 of the isolation member 140 has a second width W2 along the third direction Y, wherein the first width W1 is substantially equal to or less than the second width W2. In some embodiments, the first width W1 is 200 nm.

The isolation member 140 includes a first dielectric material and is free of metallic material. In some embodiments, the first dielectric material includes oxide or the like. In some embodiments, the isolation member 140 includes silicon dioxide or the like. In some embodiments, the isolation member 140 includes a high-k (high dielectric constant) dielectric material, such as HfAlO, ZrO₂, aluminum oxide, titanium oxide, or the like.

In some embodiments, the isolation member 140 is surrounded by a barrier layer 144 disposed between the isolation member 140 and the substrate 110. In some embodiments, the barrier layer 144 is disposed between and in contact with the isolation member 140 and the capacitor structure 120. The barrier layer 144 is disposed on a sidewall of the isolation member 140. The barrier layer 144 includes a second dielectric material such as oxide or the like. In some embodiments, the barrier layer 144 includes silicon dioxide or the like. In some embodiments, the barrier layer 144 includes a high-k (high dielectric constant) dielectric material, such as HfAlO, ZrO₂, aluminum oxide, titanium oxide, or the like. In some embodiments, the barrier layer 144 and the isolation member 140 include different materials. In some embodiments, an interface 145 is between the barrier layer 144 and the isolation member 140.

In some embodiments, the capacitor structure 120 includes a first isolation layer 126, a first electrode layer 123, a first dielectric 124, a second electrode layer 125, and a second isolation layer 127. In some embodiments, the capacitor structure 120 includes several first electrode layers 123, several first dielectrics 124, and several second electrode layers 125 alternately disposed. In some embodiments, the several first electrode layers 123, the several first dielectrics 124, and the several second electrode layers 125 are sequentially stacked between the first isolation layer 126 and the second isolation layer 127.

In some embodiments, the first isolation layer 126 is disposed over the first surface 110a of the substrate 110 and conformal to the first recess 111. The first isolation layer 126 includes dielectric material such as oxide or the like. In some embodiments, the first isolation layer 126 includes silicon dioxide or the like. In some embodiments, the first isolation layer 126 includes a high-k (high dielectric constant) dielectric material, such as hafnium aluminum oxide (HfAlO), zirconium dioxide (ZrO₂), aluminum oxide, titanium oxide, or the like.

The first electrode layer 123 is disposed over and conformal to the first isolation layer 126. The first electrode layer 123 is disposed over the first surface 110a of the substrate 110 and is at least partially disposed within the first recess 111. In some embodiments, the first electrode layer 123 includes a first body portion 123a disposed in and conformal to the first recess 111 and a first extending portion 123b disposed over the first surface 110a of the substrate 110. In some embodiments, the first body portion 123a and the first extending portion 123b are integral and continuous. The first electrode layer 123 includes conductive material such as copper, titanium nitride (TiN), polysilicon or the like.

In some embodiments, the first isolation layer 126 is disposed between the first electrode layer 123 and the substrate 110. In some embodiments, the first electrode layer 123 is a bottom electrode of the capacitor structure 120.

The first dielectric 124 is disposed over and conformal to the first electrode layer 123. The first dielectric 124 is disposed over the first surface 110a of the substrate 110 and is at least partially disposed within the first recess 111. In some embodiments, the first electrode layer 123 is enclosed by the first dielectric 124 and the first isolation layer 126. The first dielectric 124 includes dielectric material such as nitride, oxide or the like. In some embodiments, the first dielectric 124 includes a high-k dielectric material, such as HfAlO, ZrO₂, aluminum oxide, titanium oxide, or the like.

The second electrode layer 125 is disposed over and conformal to the first dielectric 124. The second electrode layer 125 is disposed over the first surface 110a of the substrate 110 and is at least partially disposed within the first recess 111. In some embodiments, the second electrode layer 125 covers the first dielectric 124 and the first body portion 123a and the first extending portion 123b of the first electrode layer 123. In some embodiments, the first dielectric 124 is entirely covered by the second electrode layer 125. In some embodiments, the second electrode layer 125 is a top electrode of the capacitor structure 120. The second electrode layer 125 includes conductive material such as copper, titanium nitride (TiN), polysilicon or the like.

In some embodiments, the second electrode layer 125 includes a second body portion 125a and a second extending portion 125b. The second body portion 125a is disposed in the first recess 111 and over the first body portion 123a of the first electrode layer 123. The second extending portion 125b is disposed over the first extending portion 123b of the first electrode layer 123. In some embodiments, the second body portion 125a and the second extending portion 125b of the second electrode layer 125 are integral and continuous.

The second isolation layer 127 is disposed over the first isolation layer 126, the first electrode layer 123, the first dielectric 124, and the second electrode layer 125. In some embodiments, the second isolation layer 127 covers the first isolation layer 126, the first electrode layer 123, the first dielectric 124, and the second electrode layer 125. The second isolation layer 127 is disposed above the first recess 111. In some embodiments, the second isolation layer 127 is at least partially disposed within the first recess 111. In some embodiments, the second body portion 125a of the second electrode layer 125 surrounds a portion of the second isolation layer 127. In some embodiments, the second isolation layer 127 is conformal to the second electrode layer 125.

The second isolation layer 127 includes dielectric material such as oxide or the like. In some embodiments, the second isolation layer 127 includes silicon dioxide or the like. In some embodiments, the second isolation layer 127 includes a high-k (high dielectric constant) dielectric material, such as HfAlO, ZrO₂, aluminum oxide, titanium oxide, or the like. In some embodiments, the second isolation layer 127 and the first isolation layer 126 include a same material.

In some embodiments, the semiconductor structure 100 includes a first dielectric layer 113 disposed over the substrate 110 and the capacitor structure 120. In some embodiments, the first dielectric layer 113 is disposed on the first surface 110a of the substrate 110 and the second isolation layer 127 of the capacitor structure 120. The first dielectric layer 113 includes dielectric material such as oxide or the like. In some embodiments, the second isolation layer 127 and the first dielectric layer 113 include a same material or different materials. In some embodiments, an interface between the second isolation layer 127 and the first dielectric layer 113 is absent.

In some embodiments, the semiconductor structure 100 includes a first nitride layer 113a disposed over the substrate 110 and the capacitor structure 120. In some embodiments, the first nitride layer 113a is disposed on the first surface 110a of the substrate 110 and the second isolation layer 127 of the capacitor structure 120. In some embodiments, the semiconductor structure 100 includes a first oxide layer 113b disposed over the first nitride layer 113a. In some embodiments, the semiconductor structure 100 includes a second nitride layer 113c disposed over the first oxide layer 113b. In some embodiments, the semiconductor structure 100 includes a second oxide layer 113d disposed over the second nitride layer 113c. The first nitride layer 113a is similar to the second nitride layer 113c. The first oxide layer 113b is similar to the second oxide layer 113d. In some embodiments, the first nitride layer 113a, the first oxide layer 113b, the second nitride layer 113c and the second oxide layer 113d are sequentially stacked over the first surface 110a of the substrate 110. In some embodiments, several nitride layers and several oxide layers are alternately disposed over the substrate 110.

An interconnect structure 130 is disposed above and electrically connected to the capacitor structure 120. In some embodiments, the interconnect structure 130 includes a first conductive via 131 electrically coupled to the first electrode layer 123 and a second conductive via 132 electrically coupled to the second electrode layer 125. Each of the first conductive via 131 and the second conductive via 132 are at least partially surrounded by the first dielectric layer 113. In some embodiments, the first conductive via 131 and the second conductive via 132 extend through the first nitride layer 113a, the first oxide layer 113b, the second nitride layer 113c and the second oxide layer 113d.

In some embodiments, each of the first conductive via 131 and the second conductive via 132 extends through the first dielectric layer 113 and is surrounded by one or more third isolation layers 134. The third isolation layers 134 are disposed on sidewalls 133 of the first conductive via 131 and the second conductive via 132. In some embodiments, each of the third isolation layers 134 surrounds a corresponding first conductive via 131 and a corresponding second conductive via 132.

The third isolation layer 134 is disposed between the first dielectric layer 113 and the first conductive via 131, and between the first dielectric layer 113 and the second conductive via 132. In some embodiments, the third isolation layer 134 extends through the first dielectric layer 113. The third isolation layer 134 is at least partially surrounded by the first nitride layer 113a, the first oxide layer 113b, the second nitride layer 113c and the second oxide layer 113d. In some embodiments, at least a portion of the third isolation layer 134 is disposed between the first conductive via 131 and the second conductive via 132.

In some embodiments, each of the first conductive via 131 and the second conductive via 132 has a third width W3 along the third direction Y, wherein the third width W3 is between 40 and 130 nm.

Each of the first conductive via 131 and the second conductive via 132 includes conductive material such as copper, silver or the like. In some embodiments, the first conductive via 131 and the second conductive via 132 include a same material. The third isolation layer 134 includes dielectric material such as oxide or the like. In some embodiments, the third isolation layer 134 includes silicon dioxide or the like. In some embodiments, the third isolation layer 134 includes a high-k (high dielectric constant) dielectric material, such as HfAlO, ZrO₂, aluminum oxide, titanium oxide, or the like. In some embodiments, the third isolation layer 134 and the second isolation layer 127 include a same material or different materials. In some embodiments, an interface between the third isolation layer 134 and the second isolation layer 127 is absent.

In some embodiments, the first conductive via 131 and the second conductive via 132 have different lengths, such that the first conductive via 131 contacting the first electrode layer 123 is longer than the second conductive via 132 contacting the second electrode layer 125. In some embodiments, the first conductive via 131 contacting the first electrode layer 123 is electrically isolated from the second electrode layer 125. In some embodiments, the second conductive via 132 contacting the second electrode layer 125 is electrically isolated from the first electrode layer 123.

In some embodiments, the covering portion 142 of the isolation member 140 is disposed adjacent to the interconnect structure 130. The covering portion 142 extends through and is surrounded by the first dielectric layer 113. The covering portion 142 is at least partially surrounded by the first nitride layer 113a, the first oxide layer 113b, the second nitride layer 113c and the second oxide layer 113d. In some embodiments, at least a portion of the first dielectric layer 113 is disposed between the interconnect structure 130 and the covering portion 142. A third distance S3 between the covering portion 142 of the isolation member 140 and the interconnect structure 130 is between 0.13 and 0.4 μm.

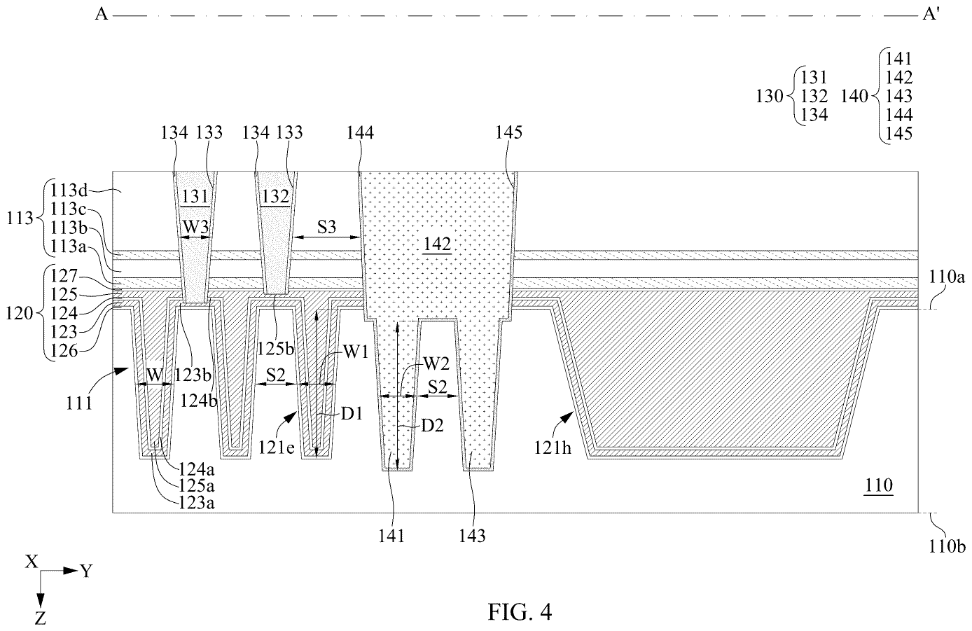

FIG. 4 is a schematic cross-sectional view taken along a line A-A′ in FIG. 1. The semiconductor structure 100 illustrated in FIG. 4 is similar to the semiconductor structure 100 illustrated in FIGS. 1, 2 and 3, except that a portion of the covering portion 142 of the isolation member 140 of the semiconductor structure 100 of FIG. 4 is disposed lower than the first surface 110a of the substrate 110. In some embodiments, a portion of the covering portion 142 extends into the substrate 110 in the first direction Z, and the covering portion 142 is surrounded by the substrate 110, the capacitor structure 120 and the first dielectric layer 113. In some embodiments, the covering portion 142 is in contact with the substrate 110, the capacitor structure 120 and the first dielectric layer 113. In some embodiments, the entire first plug portion 141 and the entire second plug portion 142 of the isolation member 140 are disposed lower than the first surface 110a of the substrate 110.

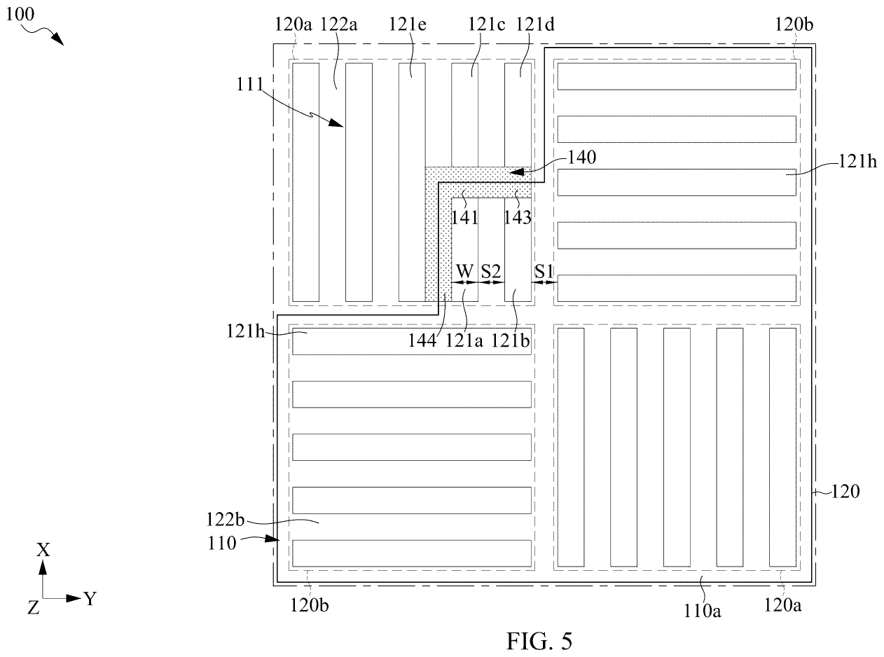

FIG. 5 is a schematic top view of a semiconductor structure in accordance with some embodiments of the present disclosure. The semiconductor structure 100 illustrated in FIG. 5 is similar to the semiconductor structure 100 illustrated in FIGS. 1, 2 and 3, except that the isolation member 140 of the semiconductor structure 100 of FIG. 5 further includes an elongated portion 144 coupled to the first plug portion 141, and the isolation member 140 has an L shape from a top view perspective. In some embodiments, the elongated portion 144 is disposed between the first plug element 121a and the fifth plug element 121e, and extends along the second direction X. In some embodiments, the elongated portion 144 is in contact with the first plug element 121a and the fifth plug element 121e. In some embodiments, the elongated portion 144 is disposed adjacent to the first plug element 121a, and the first plug element 121a is disposed between the elongated portion 144 and the second plug element 121b. In some embodiments, the first plug portion 141, the second plug portion 143, the covering member 142 and the elongated portion 144 are integral and continuous.

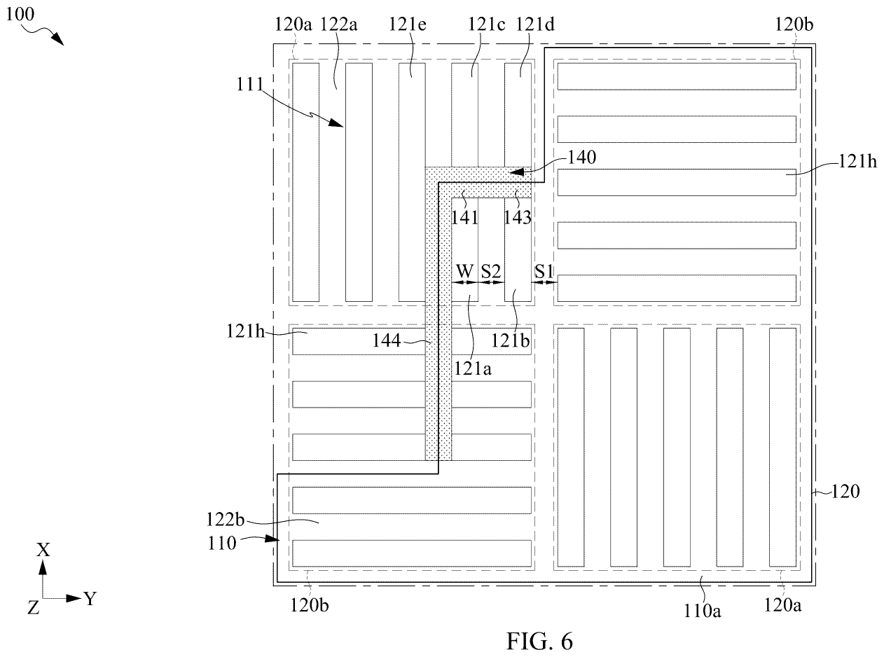

FIG. 6 is a schematic top view of a semiconductor structure in accordance with some embodiments of the present disclosure. The semiconductor structure 100 illustrated in FIG. 6 is similar to the semiconductor structure 100 illustrated in FIG. 4, except that the elongated portion 144 of the isolation member 140 of the semiconductor structure 100 of FIG. 6 further extends to the second-type plug group 120b. In some embodiments, the isolation member 140 is in contact with the first-type plug group 120a and the second-type plug group 120b. In some embodiments, the elongated portion 144 of the isolation member 140 separates the sixth plug element 121h of the second-type plug group 120b into two segments. In some embodiments, the elongated portion 144 of the isolation member 140 separates the plug element of the second-type plug group 120b into segments.

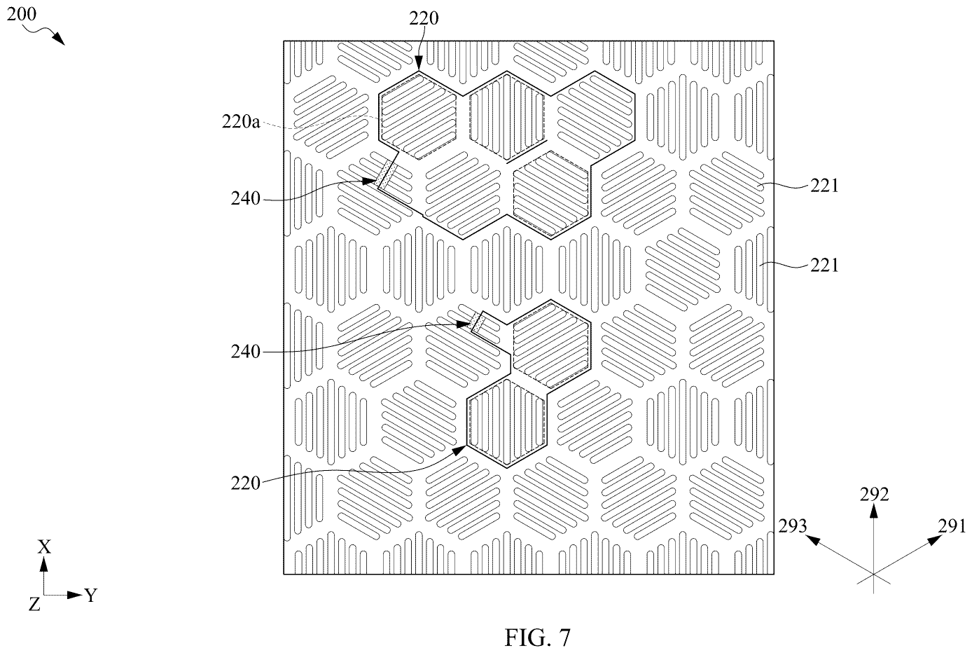

FIG. 7 is a schematic top view of a semiconductor structure in accordance with some embodiments of the present disclosure. The semiconductor structure 200 illustrated in FIG. 7 includes a capacitor structure 220 having third-type plug groups 220a, wherein each third-type plug group 220a has a contour with a hexagon shape.

In some embodiments, referring to FIG. 7, each third-type plug group 220a includes seven plug elements 221. The plug elements 221 in each third-type plug group 220a are elongated and have different lengths. The plug elements 221 in each third-type plug group 220a are parallel to each other and extend in one of three directions 291, 292 and 293. An angle between any two of the three directions 291, 292 and 293 is 120 degrees. Since the plug elements 221 in the third-type plug groups 220a extend in three different directions 291, 292 and 293, a stress caused by high-density trenches disposed in a large chip area will have components in three directions, thereby reducing warpage of a chip. Those skilled in the art can appreciate a semiconductor structure 200 that includes seven plug elements 221 extending in more than three directions 291, 292 and 293.

In some embodiments, the capacitor structure 220 can be considered as a bank of available plug elements 221, and any number of the plug elements 221 can form the capacitor structure 220 with a capacitance proportional to the number of plug elements 221. Once the design requirements of a chip to be connected to the capacitor structure 220 is known, a size and a scope of the capacitor structure 220 can be calculated accordingly. In some embodiments, the number of the plug elements 221 is calculated by dividing the target capacitance for the chip by the unit capacitance that each plug element 221 provides.

It should be understood that although the capacitor structure 220 is organized by the third-type plug groups 220a, the division does not have to follow the boundaries between the third-type plug groups 220a. In other words, the boundaries between the capacitor structures 220 can cross the boundaries between the third-type plug groups 220a. In some embodiments, an isolation member 240 divides the third-type plug group 220a in a flexible manner. As such, a portion of the third-type plug group 220a can be part of (i.e., can be included in) one of the capacitor structures 220, while another portion of the third-type plug group 220a can be part of (i.e., can be included in) another capacitor structure 220 or can be unused and reserved for future use.

In some embodiments, all the plug elements 221 of one of the third-type plug groups 220a are used (i.e., assigned to one of the capacitor structures 220). In some embodiments, a portion of the third-type plug group 220a can be unused (i.e., not assigned to any capacitor structure 220, and reserved for future use).

In some embodiments, the plug elements 221 assigned to one capacitor structure 220 are electrically connected. Routing resources can be allocated according to geometry, location, and size of the corresponding capacitor structure 220.

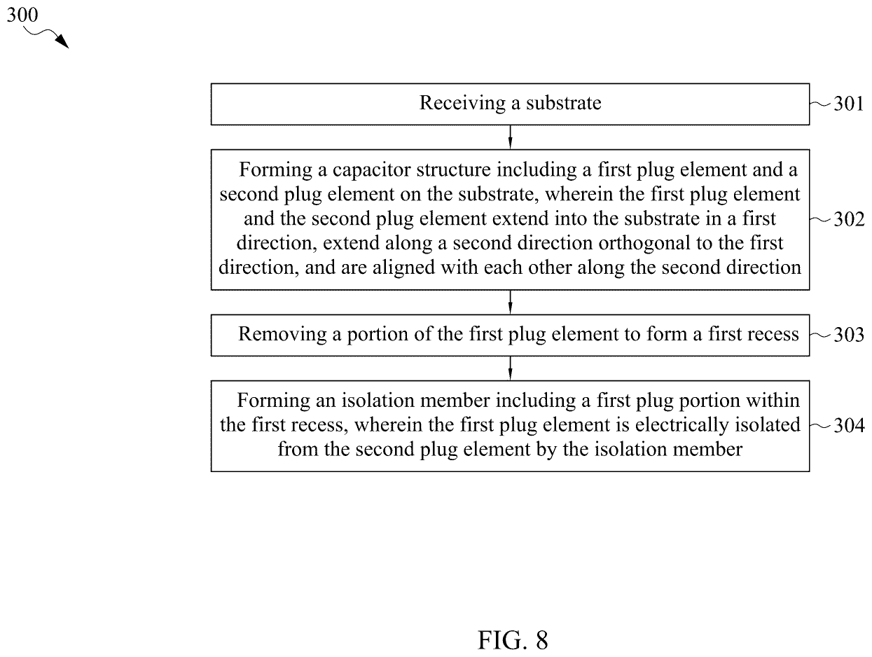

In the present disclosure, a method of manufacturing the semiconductor structure 100 is also disclosed. In some embodiments, the semiconductor structure 100 is fabricated by a method 300. The method 300 includes a number of operations, and the description and illustration are not deemed as a limitation to the sequence of operations. FIG. 8 is an embodiment of the method 300 of manufacturing the semiconductor structure 100. The method 300 includes a number of operations (301, 302, 303 and 304). In operation 301, a substrate is received. In operation 302, a capacitor structure including a first plug element and a second plug element is formed on the substrate, wherein the first plug element and the second plug element extend into the substrate in a first direction, extend along a second direction orthogonal to the first direction, and are aligned with each other along the second direction. In operation 303, a portion of the first plug element is removed to form a first recess. In operation 304, an isolation member including a first plug portion within the first recess is formed, wherein the first plug element is electrically isolated from the second plug element by the isolation member. In some embodiments, the semiconductor structure 100 is fabricated by the method 300.

According to some embodiments of the present disclosure, a method for manufacturing a semiconductor structure is disclosed. In some embodiments, the semiconductor structure 100 is fabricated by a method 400. FIG. 9 is a flowchart of the method 400 in accordance with some embodiments. The method 400 includes a number of operations (401 to 406), and descriptions and illustrations are not deemed as a limitation to a sequence of the operations. Additional steps can be provided before, during, and after the operations shown in FIG. 9, and some of the operations described below can be replaced or eliminated in other embodiments of the method 400. An order of the operations may be interchangeable. In some embodiments, the semiconductor structure 100 is fabricated by the method 400.

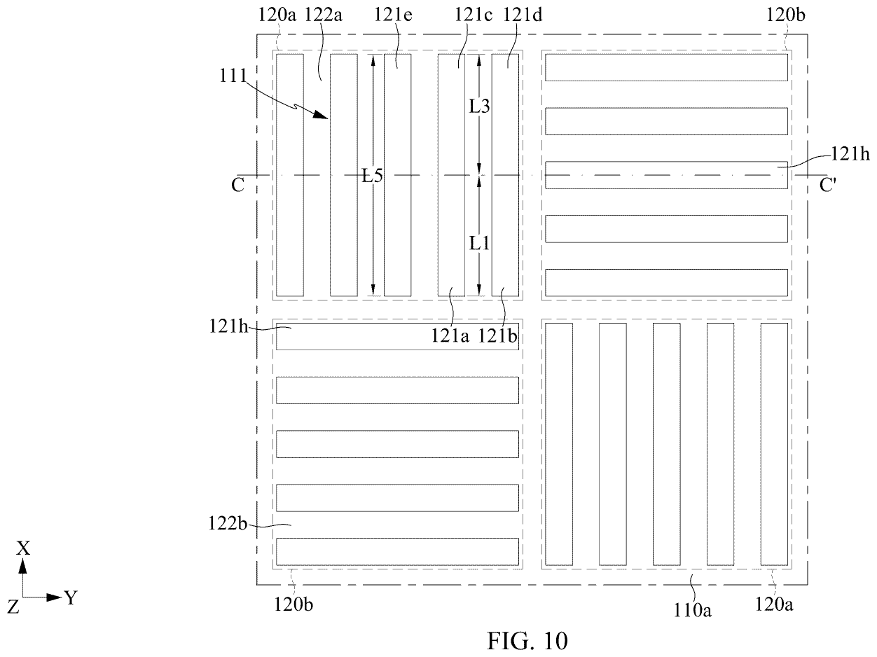

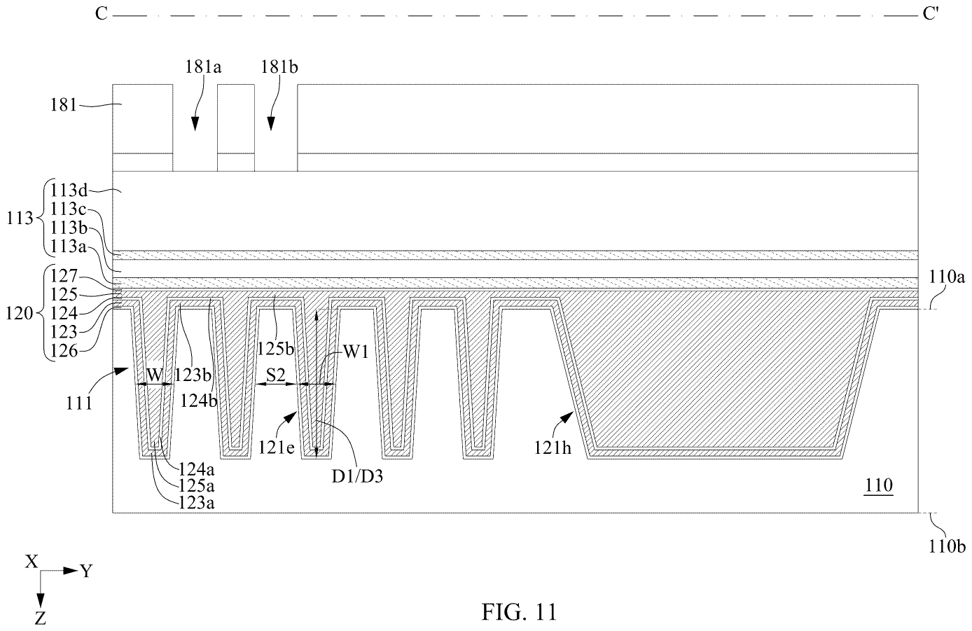

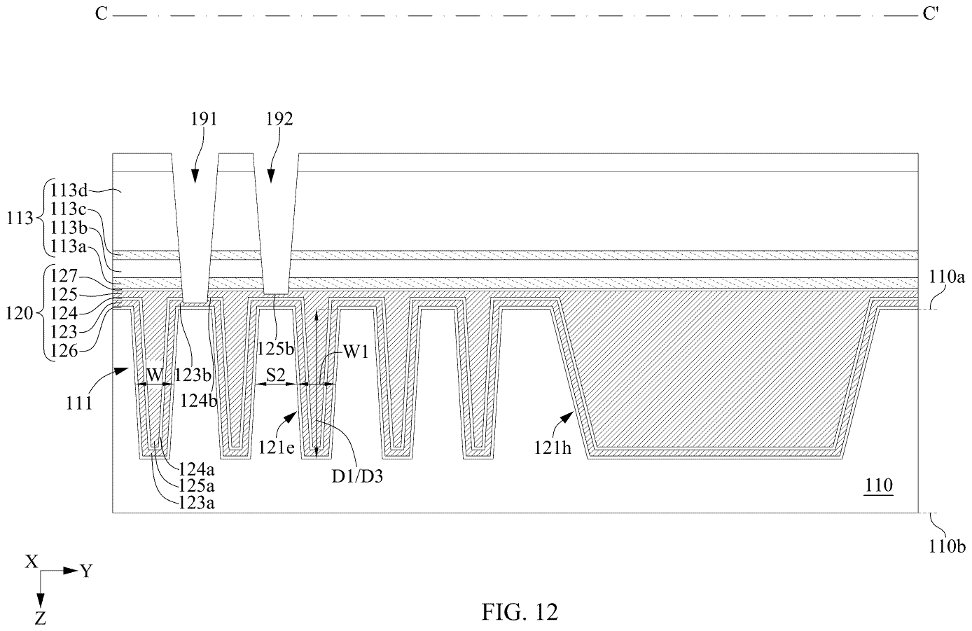

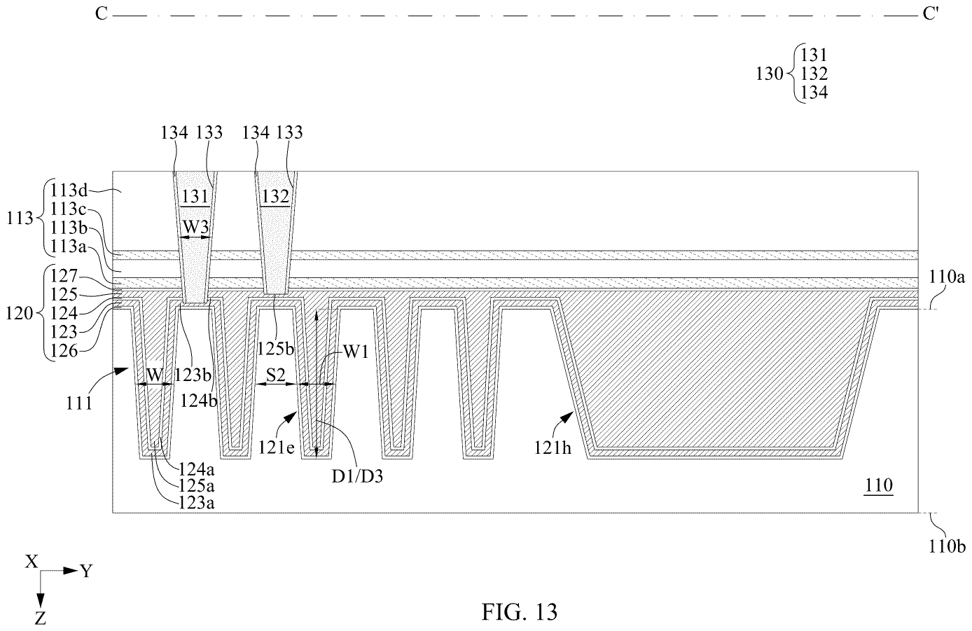

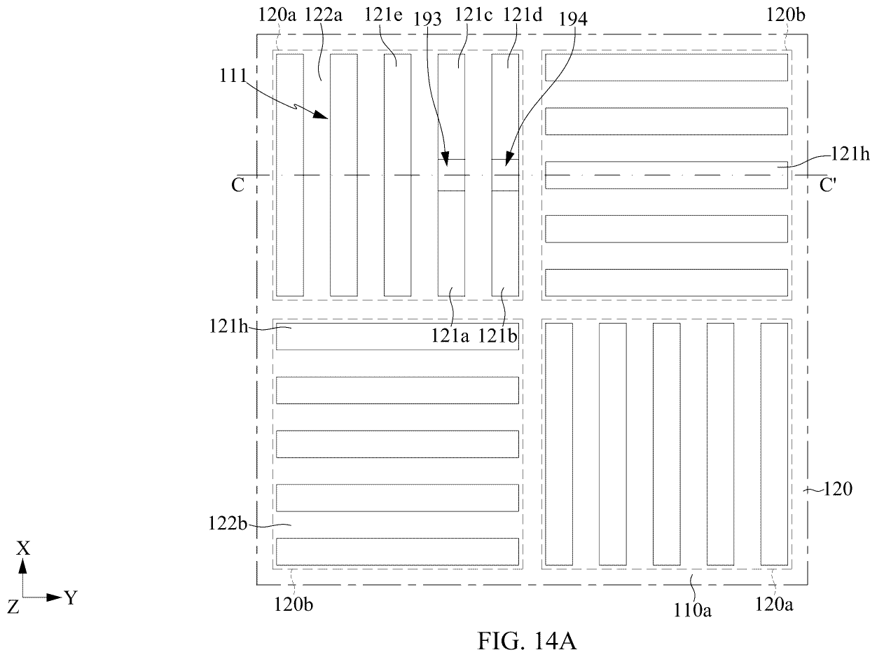

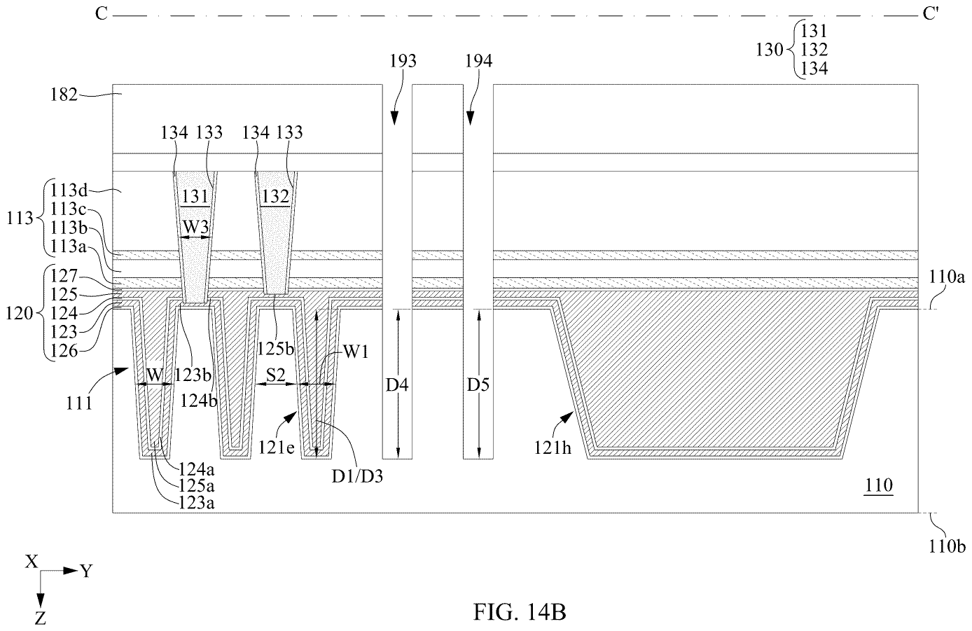

FIGS. 10, 14A, 15A, 16A and 17A are schematic top views of one or more stages of the method 400 of manufacturing a semiconductor structure in accordance with some embodiments of the present disclosure. FIGS. 14B, 15B, 16B and 17B are schematic cross-sectional views taken along a line C-C′ in FIGS. 14A, 15A, 16A and 17A, respectively. FIGS. 11, 12, 13 and 18 are schematic cross-sectional views of one or more stages of the method 400 of manufacturing a semiconductor structure in accordance with some embodiments of the present disclosure.

The method 400 begins with operation 401. Operation 401 includes receiving a substrate 110 having a first recess 111. In some embodiments, operation 401 of the method 400 is similar to operation 301 of the method 300. In some embodiments, the substrate 110 is provided as shown in FIGS. 10 and 11. The substrate 110 includes semiconductor material.

In operation 401, referring to FIGS. 10 and 11, the first recess 111 is formed on a first surface 110a of the substrate 110. In some embodiments, the first recess 111 is formed in the substrate 110 and extends from the first surface 110a toward a second surface 110b of the substrate 110. In some embodiments, the first recess 111 is formed by etching or any other suitable operation. The etching may be performed using acceptable photolithography techniques.

The method 400 continues with operation 402. Operation 402 includes forming a capacitor structure 120 including a first plug element 121a and a third plug element 121c on the substrate 110, wherein the first plug element 121a and the third plug element 121c extend into the substrate 110 in a first direction Z, extend along a second direction X orthogonal to the first direction Z, and are aligned with each other along the second direction X. In some embodiments, a portion of the capacitor structure 120 is disposed within the first recess 111. In some embodiments, operation 402 of the method 400 is similar to operation 302 of the method 300. In some embodiments, the first plug element 121a and the third plug element 121c are integral and continuous.

In some embodiments, formation of the capacitor structure 120 further includes forming a second plug element 121b and a fourth plug element 121d on the substrate 110, wherein the second plug element 121b and the fourth plug element 121d extend into the substrate 110 in the first direction Z, extend along the second direction X orthogonal to the first direction Z, and are aligned with each other along the second direction X. In some embodiments, the first plug element 121a is disposed adjacent to the second plug element 121b, and the third plug element 121c is disposed adjacent to the fourth plug element 121d. In some embodiments, the second plug element 121b and the fourth plug element 121d are integral and continuous.

In some embodiments, formation of the capacitor structure 120 further includes forming a fifth plug element 121e on the substrate 110, wherein the fifth plug element 121e extends into the substrate 110 in a first direction Z, extends along the second direction X, and is disposed adjacent to the first plug element 121a and the third plug element 121c.

The first plug element 121a has a first length L1 along the second direction X, the third plug element 121c has a third length L3 along the second direction X, and the fifth plug element 121e has a fifth length L5 along the second direction X. In some embodiments, the fifth length L5 is substantially equal to a sum of the first length L1 and the third length L3.

In some embodiments, operation 402 includes disposing a first isolation layer 126 on the first surface 110a and extending into the first recess 111. In some embodiments, the first recess 111 has the first isolation layer 126 formed therein. In some embodiments, the first isolation layer 126 is formed over the first surface 110a of the substrate 110 and in the first recess 111. In some embodiments, the first isolation layer 126 is conformal to the first recess 111 and a portion of the first surface 110a of the substrate 110. The first isolation layer 126 is deposited over the surface 110a of the substrate 110 and then planarized, such as by respective CMP processes. The first isolation layer 126 is deposited by physical vapor deposition (PVD), CVD, sputter deposition, or another technique for depositing the selected material.

In operation 402, the capacitor structure 120 is formed at least partially within the first recess 111. The formation of the capacitor structure 120 includes disposing a first electrode layer 123 over the first isolation layer 126, disposing a first dielectric 124 over the first electrode layer 123, and disposing a second electrode layer 125 to cover the first dielectric 124 and the first electrode layer 123. In some embodiments, the formation of the capacitor structure 120 further includes disposing a second isolation layer 127 to cover the first electrode layer 123, the first dielectric 124, and the second electrode layer 125. In some embodiments, the capacitor structure 120 is formed by sequentially disposing the first electrode layer 123, the first dielectric 124, and the second electrode layer 125.

In some embodiments, a portion of the first electrode layer 123 is disposed in and conformal to the first recess 111. The first electrode layer 123 may be deposited by PVD, CVD, sputter deposition, or another technique for depositing the selected material.

In some embodiments, the first dielectric 124 is conformal to the first electrode layer 123. The first dielectric 124 may be deposited over the first electrode layer 123. The first dielectric 124 may be deposited by PVD, CVD, sputter deposition, or another technique for depositing the dielectric material.

In some embodiments, the second electrode layer 125 is formed conformal to the first dielectric 124. The second electrode layer 125 may be deposited by PVD, CVD, sputter deposition, or another technique for depositing the selected material.

In some embodiments, the second isolation layer 127 is formed over the second electrode layer 125. In some embodiments, the second isolation layer 127 is disposed over the first surface 110a of the substrate 110.

In some embodiments, in operation 402, the capacitor structure 120 is formed at least partially disposed within the first recess 111 as shown in FIGS. 10 and 11. In some embodiments, the first recess 111 has a third depth D3 into the substrate 110 along the first direction Z, and each of the thusly formed first, second, third, fourth, fifth and sixth plug elements 121a, 121b, 121c, 121d, 121e and 121h has a first depth D1 into the substrate 110 along the first direction Z, wherein the first depth D1 is substantially equal to the third depth D3.

In some embodiments, the capacitor structure 120 is formed by sequentially disposing the first isolation layer 126, the first electrode layer 123, the first dielectric 124, the second electrode layer 125, and the second isolation layer 127.

The method 400 continues with operation 403. Operation 403 includes disposing a first dielectric layer 113 over the capacitor structure 120. In some embodiments, the first dielectric layer 113 is provided as shown in FIG. 11. In some embodiments, a first dielectric layer 113 is disposed over the substrate 110 and the capacitor structure 120. The first dielectric layer 113 is disposed over the first surface 110a of the substrate 110 and the second isolation layer 127. In some embodiments, the first dielectric layer 113 is disposed by deposition, CVD or any other suitable operation. The first dielectric layer 113 includes a first dielectric material.

The method 400 continues with operation 404. Operation 404 includes forming an interconnect structure 130 disposed over and electrically connected to the capacitor structure 120. In some embodiments, the interconnect structure 130 is formed after the formation of the capacitor structure 120 and the first dielectric layer 113.

In some embodiments, as shown in FIG. 11, a photoresist 181 is formed over the first dielectric layer 113, and the photoresist 181 is patterned. The photoresist 181 may be formed by spin coating and may be exposed to light for patterning. The patterning operation forms openings 181a through the photoresist 181 to expose portions of the first dielectric layer 113.

Referring to FIGS. 12 and 13, the portions of the first dielectric layer 113 exposed by the photoresist 181 are removed to form an interconnect structure 130, wherein the interconnect structure 130 includes a first conductive via 131 electrically coupled to the first electrode layer 123 and a second conductive via 132 electrically coupled to the second electrode layer 125.

In some embodiments, referring to FIG. 12, the portions of the first dielectric layer 113 are removed to form several openings extending through the first dielectric layer 113. In some embodiments, a first opening 191 and a second opening 192 are formed during the removal of the portions of the first dielectric layer 113. In some embodiments, the first electrode layer 123 is exposed through the first opening 191, and the first opening 191 extends through the second isolation layer 127, the second electrode layer 125, and the first dielectric 124. In some embodiments, the second electrode layer 125 is exposed through the second opening 192, and the second opening 192 extends through the second isolation layer 127. The photoresist 181 is removed after the first opening 191 and the second opening 192 are formed. The photoresist 181 is removed by an acceptable washing or stripping process, such as a process using an oxygen plasma or the like.

In some embodiments, referring to FIG. 13, the first conductive via 131 and the second conductive via 132 are formed within the first opening 191 and the second opening 192, respectively. In some embodiments, each of the first conductive via 131 and the second conductive via 132 is surrounded by a corresponding third isolation layer 134. The third isolation layers 134 are formed within the first opening 191 and the second opening 192. In some embodiments, the third isolation layers 134 are formed prior to the formation of the first conductive via 131 and the second conductive via 132. In some embodiments, the third isolation layers 134 is formed by PVD, CVD, sputter deposition, or another technique for depositing the selected material. In some embodiments, the first conductive via 131 and the second conductive via 132 are formed by electroplating, sputtering or any other suitable operation. Each of the first conductive via 131 and the second conductive via 132 is in contact with the first electrode layer 123 and the second electrode layer 125, respectively.

The method 400 continues with operation 405. Operation 405 includes removing a portion of the first plug element 121a to form a second recess 193. In some embodiments, operation 405 of the method 400 is similar to operation 303 of the method 300. In some embodiments, referring to FIGS. 14A and 14B, a photoresist 182 is formed over the first dielectric layer 113 and the interconnect structure 130, and the photoresist 182 is patterned. The photoresist 182 may be formed by spin coating and may be exposed to light for patterning. The patterning operation forms a second recess 193 through the photoresist 182, the first dielectric layer 113 and the first plug element 121a to expose portions of the substrate 110. In some embodiments, a portion of the substrate 110 is removed during the formation of the second recess 193.

In some embodiments, the patterning operation further forms a third recess 194 through the photoresist 182, the first dielectric layer 113 and the second plug element 121b to expose portions of the substrate 110. In some embodiments, a portion of the substrate 110 is removed during the formation of the third recess 194.

In some embodiments, the second recess 193 is separated from the third recess 194. In some embodiments, portions of the substrate 110, the capacitor structure 120 and the first dielectric layer 113 remain in place between the second recess 193 and the third recess 194. In some embodiments, the second recess 193 and the third recess 194 are disposed adjacent to each other and formed simultaneously. In some embodiments, the second recess 193 and the third recess 194 are aligned with each other along a third direction Y orthogonal to the first direction Z and the second direction X.

In some embodiments, the second recess 193 has a fourth depth D4 into the substrate 110 along the first direction Z, and the third recess 194 has a fifth depth D5 into the substrate 110 along the first direction Z. In some embodiments, the fourth depth D4 is substantially equal to the fifth depth D5. In some embodiments, each of the fourth depth D4 and the fifth depth D5 is substantially equal to or greater than the third depth D3 of the first recess 111 or the first depth D1 of each of the first, second, third, fourth, fifth and sixth plug elements 121a, 121b, 121c, 121d, 121e and 121h.

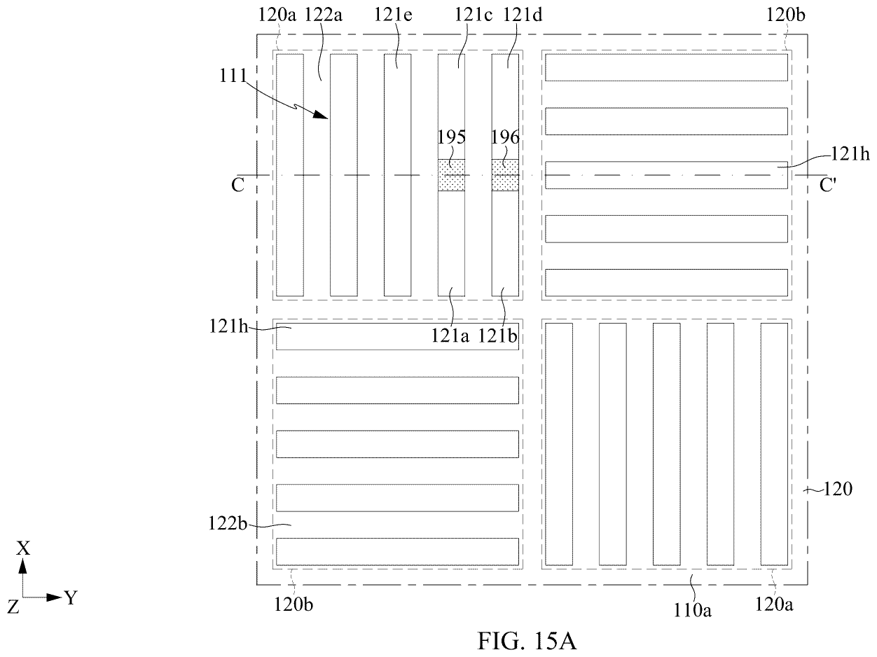

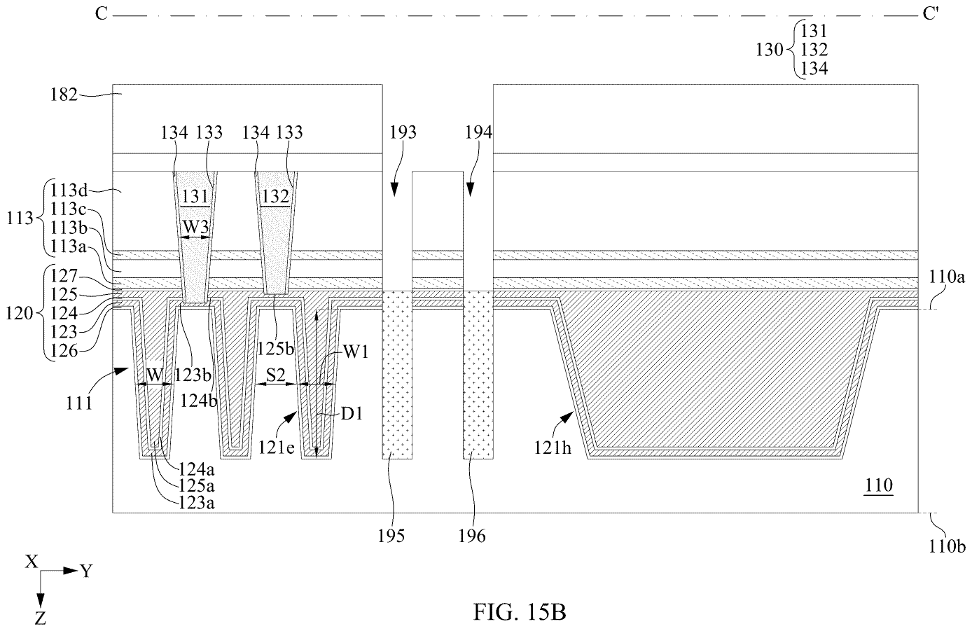

In some embodiments, referring to FIGS. 15A and 15B, a first photoresist plug 195 and a second photoresist plug 196 are formed in a portion of the second recess 193 and a portion of the third recess 194, respectively. The first photoresist plug 195 and the second photoresist plug 196 are surrounded by and in contact with the substrate 110 and the capacitor structure 120. In some embodiments, a portion of the photoresist 182 between the second recess 193 and the third recess 194 is removed.

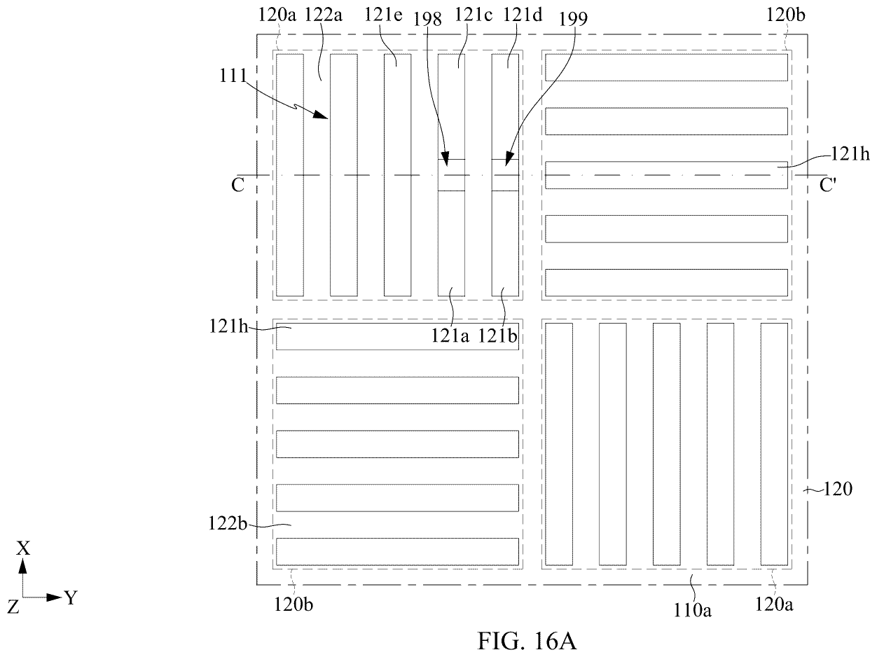

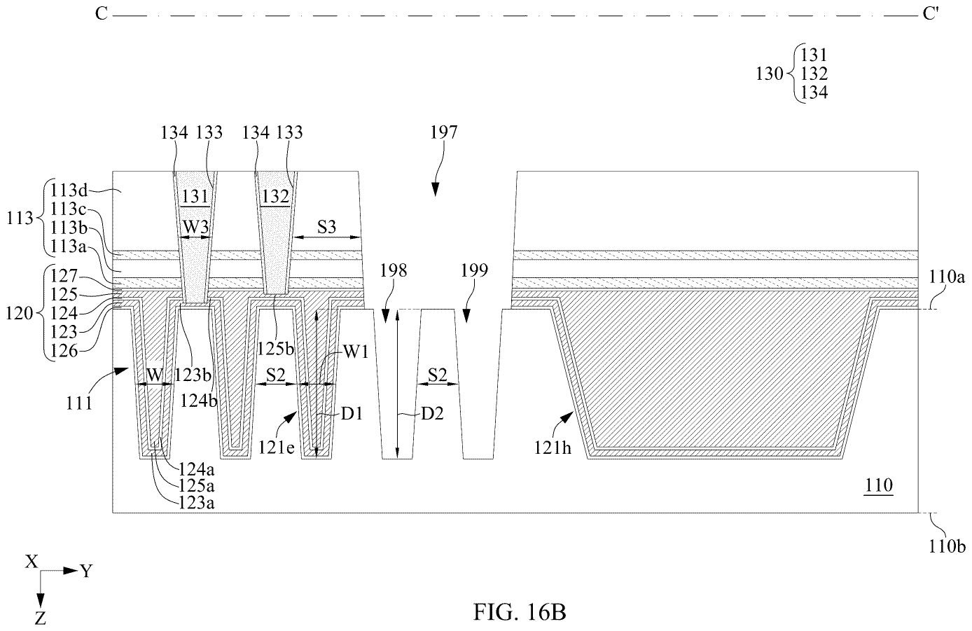

In some embodiments, referring to FIGS. 16A and 16B, the portions of the first dielectric layer 113 exposed by the photoresist 182 and portions of the capacitor structure 120 exposed by the photoresist 182 are removed, and a fourth recess 197 surrounded by the first dielectric layer 113 and the capacitor structure 120 is formed. In some embodiments, the first photoresist plug 195 and the second photoresist plug 196 are removed, and a fifth recess 198 and a sixth recess 199 in communication with the fourth recess 197 are formed. The first photoresist plug 195 and the second photoresist plug 196 may be removed by an acceptable etching process, such as dry etching after the formation of the fourth recess 197. In some embodiments, the fifth recess 198 and the sixth recess 199 are tapered.

The photoresist 182 is removed after the formation of the fourth recess 197, the fifth recess 198 and sixth recess 199. The photoresist 182 may be removed by an acceptable washing or stripping process, such as a process using an oxygen plasma or the like.

The method 400 continues with operation 406. Operation 406 includes forming an isolation member 140 including a first plug portion 141 within the second recess 193 and a covering member 142 over the substrate 110 and coupled to the first plug portion 141, wherein the first plug element 121a is electrically isolated from the third plug element 121c by the isolation member 140. In some embodiments, operation 406 of the method 400 is similar to operation 304 of the method 300.

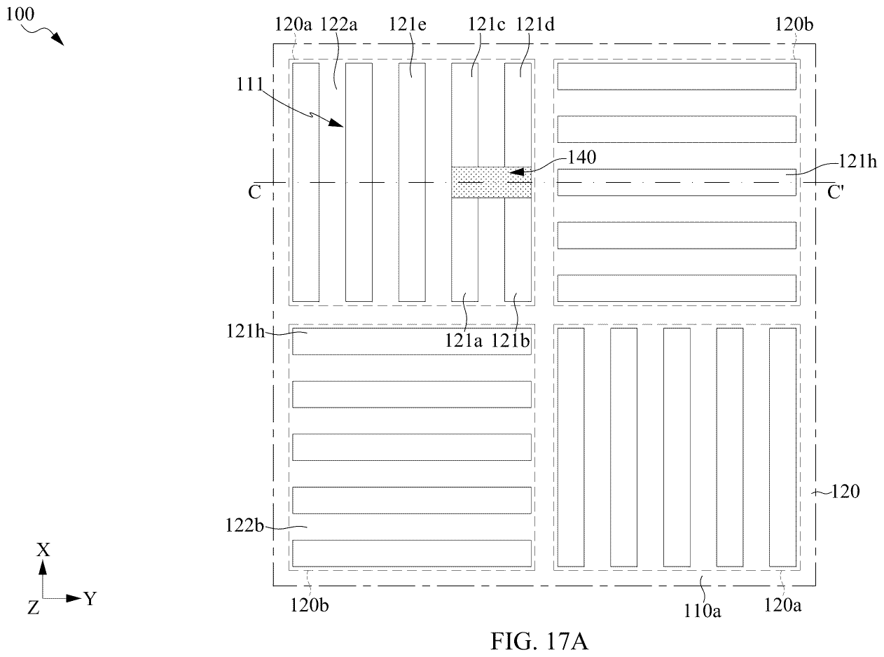

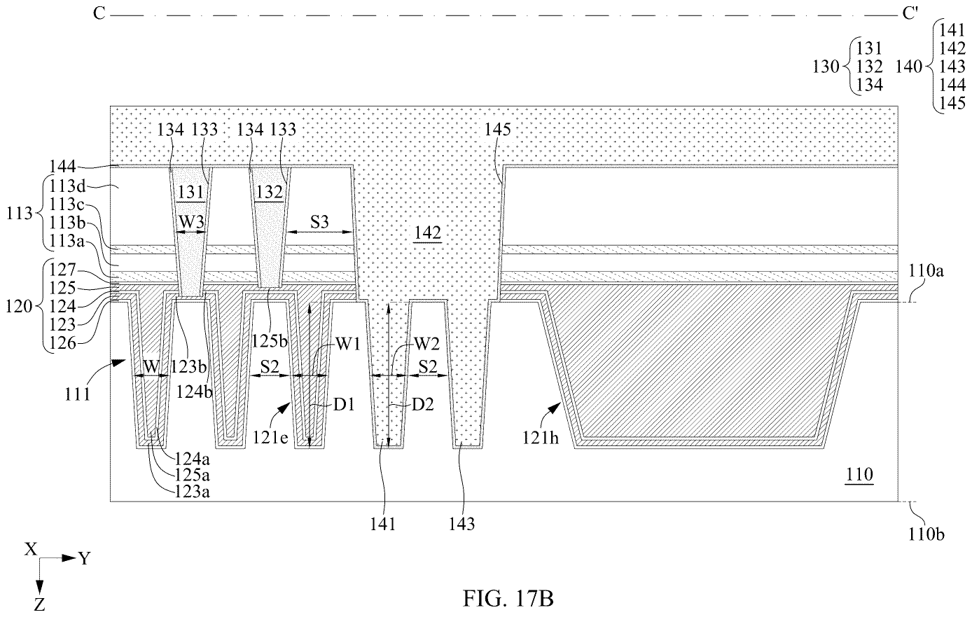

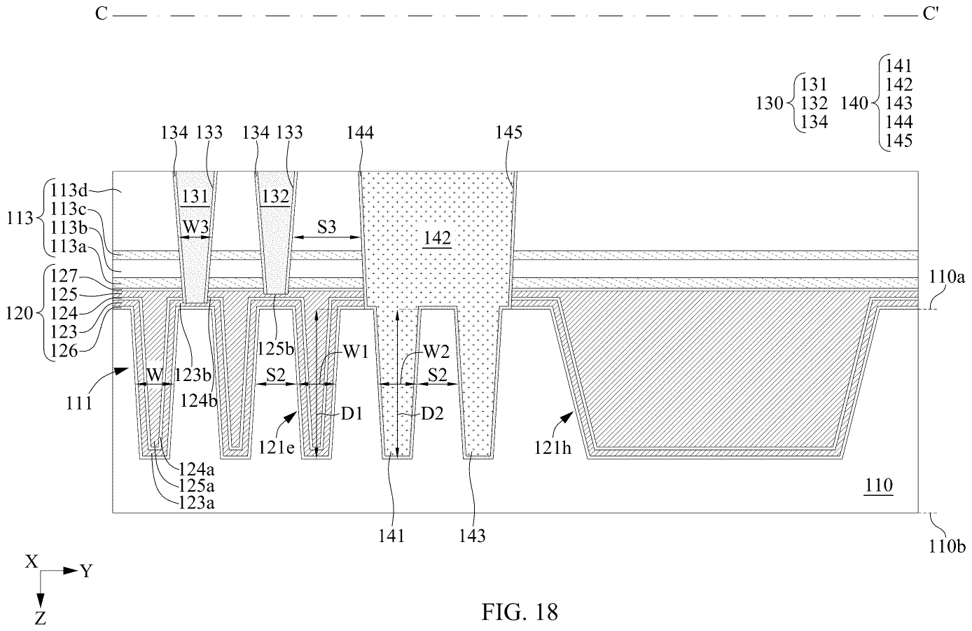

In some embodiments, referring to FIGS. 17A and 17B, the first plug portion 141 is formed within the fifth recess 198 and the covering member 142 is disposed within the fourth recess 197, and operation 406 further includes forming a second plug portion 143 within the sixth recess 199. The first plug portion 141 and the second plug portion 143 are coupled to the covering member 142. In some embodiments, the first plug portion 141, the second plug portion 143 and the covering member 142 are integral and formed simultaneously. The interconnect structure 130 and the covering member 142 of the isolation member 140 are surrounded by the first dielectric layer 113, and a portion of the first dielectric layer 113 is disposed between the interconnect structure 130 and the covering member 142.

The first plug portion 141 is formed between the first plug element 121a and the third plug element 121c, and the first plug element 121a is electrically isolated from the third plug element 121c by the isolation member 140. The second plug portion 143 is formed between the second plug element 121b and the fourth plug element 121d, and the second plug element 121b is electrically isolated from the fourth plug element 121d by the isolation member 140.

In some embodiments, a first dielectric material is deposited into the fourth recess 197, the fifth recess 198 and the sixth recess 199, and the isolation member 140 is formed.

The first dielectric material may be deposited by PVD, CVD, sputter deposition, or another technique for depositing the selected material. In some embodiments, the isolation member 140 including silicon dioxide or the like is formed. In some embodiments, a second dielectric material such as oxide or the like is deposited into the fourth recess 197, the fifth recess 198 and the sixth recess 199 to form a barrier layer 144 before the formation of the isolation member 140. In some embodiments, the barrier layer 144 surrounds the first plug portion 141, the second plug portion 143 and the covering member 142 and is in contact with the substrate 110.

Referring to FIG. 18, in some embodiments, a planarization operation is performed to remove excess first dielectric material and second dielectric material of the isolation member 140 and planarize upper surfaces of the first dielectric layer 113. After the planarization operation, the isolation member 140 has a top surface substantially coplanar with top surfaces of the first dielectric layer 113 and the interconnect structure 130. In some embodiments, the semiconductor structure 100 is completed.

One aspect of this disclosure relates to a semiconductor structure. The semiconductor structure includes a substrate; a capacitor structure including a first plug element and a second plug element, wherein the first plug element and the second plug element extend into the substrate in a first direction, extend along a second direction orthogonal to the first direction, and are aligned with each other along the second direction; and an isolation member disposed between and in contact with the first plug element and the second plug element.

One aspect of this disclosure relates to a semiconductor structure. The semiconductor structure includes a substrate; a capacitor structure including a first plug element, a second plug element, a third plug element and a fourth plug element, wherein the first, second, third and fourth plug elements extend into the substrate in a first direction and extend along a second direction orthogonal to the first direction, the first and third plug elements are aligned with each other in the second direction, the second and fourth plug elements are aligned with each other in the second direction, the first plug element is adjacent to the second plug element, and the third plug element is adjacent to the fourth plug element; and an isolation member including a first plug portion extending into the substrate in the first direction and disposed between the first plug element and the third plug element, and a second plug portion extending into the substrate in the first direction and disposed between the second plug element and the fourth plug element.

An aspect of this disclosure relates to a method of manufacturing a semiconductor structure. The method includes receiving a substrate; forming a capacitor structure including a first plug element and a second plug element on the substrate, wherein the first plug element and the second plug element extend into the substrate in a first direction, extend along a second direction orthogonal to the first direction, and are aligned with each other along the second direction; removing a portion of the first plug element to form a first recess, and forming an isolation member including a first plug portion within the first recess. The first plug element is electrically isolated from the second plug element by the isolation member.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a substrate;
a capacitor structure including a first plug element and a second plug element, wherein the first plug element and the second plug element extend into the substrate in a first direction, extend along a second direction orthogonal to the first direction, and are aligned with each other along the second direction; and
an isolation member disposed between and in contact with the first plug element and the second plug element.

2. The semiconductor structure of claim 1, wherein the first plug element has a first length along the second direction and the second plug element has a second length along the second direction.

3. The semiconductor structure of claim 2, wherein the capacitor structure further includes a third plug element, wherein the third plug element extends along the second direction and has a third length along the second direction, wherein the third length is substantially greater than the first length and substantially greater than the second length.

4. The semiconductor structure of claim 3, wherein the third length of the third plug element is equal to a sum of the first length of the first plug element, the second length of the second plug element and a third length of the isolation member along the second direction.

5. The semiconductor structure of claim 3, wherein the third plug element is disposed adjacent to the first plug element, the second plug element and the isolation member.

6. The semiconductor structure of claim 2, wherein the capacitor structure further includes a third plug element, wherein the third plug element extends along a third direction orthogonal to the first direction and the second direction and has a third length along the third direction, wherein the third length is substantially greater than the first length and substantially greater than the second length.

7. The semiconductor structure of claim 1, further comprising:
an interconnect structure disposed over and electrically connected to the capacitor structure; and
a dielectric layer disposed over the capacitor structure and surrounding the interconnect structure.

8. The semiconductor structure of claim 7, wherein the isolation member includes a plug portion disposed between the first plug element and the second plug element, and a covering member disposed over the plug portion, wherein the covering portion is disposed adjacent to the interconnect structure and surrounded by the dielectric layer.

9. The semiconductor structure of claim 1, wherein the isolation member includes a dielectric material and is free of metallic material, and the capacitor structure includes at least two electrode layers and a dielectric layer between the at least two electrode layers.

10. The semiconductor structure of claim 1, wherein the isolation member has an L shape from a plan view.

11. A semiconductor structure, comprising:
a substrate;
a capacitor structure including a first plug element, a second plug element, a third plug element and a fourth plug element, wherein the first, second, third and fourth plug elements extend into the substrate in a first direction and extend along a second direction orthogonal to the first direction, the first and third plug elements are aligned with each other in the second direction, the second and fourth plug elements are aligned with each other in the second direction, the first plug element is adjacent to the second plug element, and the third plug element is adjacent to the fourth plug element; and
an isolation member including a first plug portion extending into the substrate in the first direction and disposed between the first plug element and the third plug element, and a second plug portion extending into the substrate in the first direction and disposed between the second plug element and the fourth plug element.

12. The semiconductor structure of claim 11, wherein the isolation member further includes a covering member disposed over the first plug portion and the second plug portion.

13. The semiconductor structure of claim 12, wherein the first plug portion, the second plug portion and the covering member are integral.

14. The semiconductor structure of claim 11, wherein a depth of the first plug portion of the isolation member along the first direction is substantially equal to or greater than a depth of the first plug element along the first direction.

15. The semiconductor structure of claim 11, wherein the isolation member further includes an elongated portion coupled to the first plug portion, wherein the elongated portion extends along the second direction and is disposed adjacent to the first plug element, and the first plug element is disposed between the elongated portion and the second plug element.

16. A method of manufacturing a semiconductor structure, comprising:
receiving a substrate;
forming a capacitor structure including a first plug element and a second plug element on the substrate, wherein the first plug element and the second plug element extend into the substrate in a first direction, extend along a second direction orthogonal to the first direction, and are aligned with each other along the second direction;
removing a portion of the first plug element to form a first recess, and
forming an isolation member including a first plug portion within the first recess,
wherein the first plug element is electrically isolated from the second plug element by the isolation member.

17. The method of claim 16, further comprising:
disposing a dielectric layer over the capacitor structure; and
forming an interconnect structure disposed over and electrically connected to the capacitor structure,
wherein the interconnect structure and a covering member of the isolation member are surrounded by the dielectric layer, and the covering member is over the substrate and coupled to the first plug portion.

18. The method of claim 16, wherein the first recess is formed by removing a portion of the substrate and a portion of the first plug element.

19. The method of claim 16, further comprising:
forming an isolation member including a first plug portion within the first recess and a covering member over the substrate and coupled to the first plug portion;
removing a portion of a third plug element adjacent to the first plug element to form a second recess; and
forming a second plug portion of the isolation member within the second recess;
wherein the covering member is coupled to the first plug portion and the second plug portion.

20. The method of claim 16, wherein the formation of the capacitor structure includes:
disposing a first electrode layer in a third recess;
disposing a first dielectric over the first electrode layer; and
disposing a second electrode layer to cover the first dielectric and the first electrode layer.
